(19) United States
(12) Patent Application Publication
(10) Pub. No.: US 2022/0245289 A1
(43) Pub. Date: Aug. 4, 2022

(54) Analyzer

(71) Applicant: Nippon Telegraph and Telephone Corporation, Tokyo (JP)

(72) Inventors: Mamoru Mizunuma, Musashino-shi, Tokyo (JP); Masayuki Tsuda, Musashino-shi, Tokyo (JP); Shingo Mineta, Musashino-shi, Tokyo (JP); Shota Oki, Musashino-shi, Tokyo (JP); Kenichi Tanigaki, Musashino-shi, Tokyo (JP)

(21) Appl. No.: 17/617,539

(22) PCT Filed: Jun. 3, 2020
(86) PCT No.: PCT/JP2020/021868

§ 371 Date: Dec. 8, 2021

(30) Foreign Application Priority Data
Jun. 17, 2019 (JP) 2019-111836

(51) Int. Cl. G06F 30/10; G06F 30/23

(52) U.S. Cl. CPC G06F 30/10; E02D 5/80; G06F 30/23

(57) ABSTRACT

A tradeoff between a model accuracy and an amount of calculation in numerical analysis that simulates an underground structure pull-out test is solved. A structure model generation unit generates a structure model obtained by modeling an underground structure. A particle generation unit sets the maximum diameter of SPH particles that does not cause indication of a time history result underestimating a pull-out resistance force that is a result of the analysis, and generates the SPH particles obtained by modeling soil that is a supporter of the underground structure. An operation unit applies coupled analysis to the structure model and the SPH particles by a finite element method and an SPH method.

### TECHNICAL FIELD

The present invention relates to an analysis technology of an underground structure buried in soil.

### BACKGROUND ART

A utility pole is one of structural objects that support the social infrastructure. To balance the force applied utility poles for extending a communication cable, a utility pole at an end is provided with a support column or a guyline. The guyline is separated into an upper guyline (steel strand wire) and a lower guyline. A guyline anchor, which is a type of the lower guyline, is buried in soil and supports the utility pole.

Since the lower guyline anchor is buried in soil, it is difficult to observe the deterioration state directly. Accordingly, it has been attempted to estimate and predict the bearing force of a structural object through numerical analysis in a computer aided engineering (CAE).

### CITATION LIST

### Patent Literature

Patent Literature 1: Japanese Patent Laid-Open No. 2018-205260

### Non-Patent Literature

Non-Patent Literature 1: Nils Karajan, Zhidong Han, Hailong Teng, Jason Wang, “On the Parameter Estimation for the Discrete-Element Method in LS-DYNA”, 13th International LS-DYNA Users Conference 2014

Non-Patent Literature 2: Nils Karajan, Zhidong Han, Hailong Teng, Jason Wang, “Interaction Possibilities of Bonded and Loose Particles”, 9th European LS-DYNA Conference 2013

### SUMMARY OF THE INVENTION

### Technical Problem

In various viewpoints, there is difficulty in a simulation of an underground structure pull-out test in which modeling is performed on an underground structure assumed to be made of rigid structural steel, and flexible argillaceous and sandy soil supporting the structure, at the same time, so as to form an integral object and coupled analysis is conducted thereto.

To deal with a problem of coupling an underground structure and soil, analysis methods are conceivable that are, for example, an element-free Galerkin method (EFGM), which is one of finite element methods (FEMs) and meshfree methods, and distinct element methods (DEMs) that deal with soil not as a continuum but as discrete bodies.

Discussion of a method for reproducing deformation of soil using EFGM encounters the following problems. The first problem is that although pulling out and deformation to some extent can be supported, there is a limitation of only simulating pulling out of about 100 mm at best. The quality of background mesh for area integration is important for EFGM. This is because possible dependency on structural mesh makes it difficult to support extreme deformation. The second problem is that effects of the gravitation hardly appear in results. A large part of the anchor pull-out load calculated using EFGM is contributed by a deformation resistance component. That is, there is a possibility that the deformation resistance of soil is excessively evaluated. The third problem is that calculation can hardly be made for soft soil owing to contact instability.

Discussion of a method for reproducing deformation of soil using DEM encounters the following problems. The first problem is that the coupling strength between soil particles is excessively underestimated. The second problem is that since soil particles are modeled as particulate discrete bodies, the model is a numerical analysis model having difficulty to find the relationship between the soil viscosity and the internal friction, such as the Mohr-Coulomb model generally used in the pedological field.

There is a problem in that measures to be taken are limited, in soil modeling, in view of the coupling strength of soil particles and the like. Certain improvement in model accuracy and analysis methods have a problem in that the amount of calculation explosively increases.

The present invention has been made in view of the above description, and has an object to solve the tradeoff between the model accuracy and the amount of calculation in numerical analysis that simulates an underground structure pull-out test.

### Means for Solving the Problem

An analyzer apparatus according to an aspect of the present invention includes: a structure model generation unit that generates a structure model obtained by modeling an underground structure; a particle generation unit that generates particles obtained by modeling soil that is a supporter of the underground structure; and an operation unit that applies coupled analysis to the structure model and the particles by a finite element method and an SPH method, wherein the particle generation unit sets a maximum diameter of the particles that does not cause indication of a time history result underestimating a pull-out resistance force that is a result of the analysis.

### Effects of the Invention

The present invention can solve the tradeoff between the model accuracy and the amount of calculation in numerical analysis that simulates an underground structure pull-out test.

### BRIEF DESCRIPTION OF DRAWINGS

FIG. 1 is a functional block diagram showing a configuration of an analyzer apparatus of this embodiment.

FIG. 2 is a flowchart showing a flow of processes of the analyzer apparatus of this embodiment.

FIG. 3 is a diagram for illustrating a guyline.

FIG. 4 is a perspective view showing a configuration of a guyline lower anchor.

FIG. 5 is a diagram for illustrating a structure model and SPH particles used for numerical analysis.

FIG. 6A shows a numerical analysis result when one-row SPH particles are on half a surface of a stabilizer plate of the guyline lower anchor.

FIG. 6B shows a numerical analysis result when two-row SPH particles are on half the surface of the stabilizer plate of the guyline lower anchor.

FIG. 6C shows a numerical analysis result when three-row SPH particles are on half the surface of the stabilizer plate of the guyline lower anchor.

### DESCRIPTION OF EMBODIMENTS

Hereinafter, embodiments of the present invention are described with reference to the drawings.

In this embodiment, in a simulation of an underground structure pull-out test, an underground structure made of rigid material, such as steel material, is dealt with by FEM, and flexible soil that is a supporter of the underground structure is dealt with by the smoothed particle hydrodynamics (SPH) method. In this embodiment, soil is modeled by discritization with particles, and the SPH method is applied. The SPH method can simulate continuum-like deformation behavior by smoothing spaces around individual particles with superposition of kernel functions. On the other hand, in determination of contact between the underground structure (FEM) and soil (SPH method), the soil particles act as points, and the underground structure acts as a plane. Accordingly, in calculation of the contact force, the particle density on the contact plane, i.e., the particle diameter, is an important element.

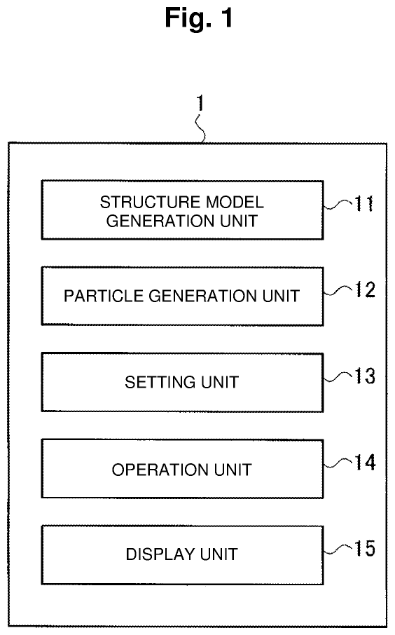

FIG. 1 is a functional block diagram showing the configuration of an analyzer apparatus 1 of this embodiment. The analyzer apparatus 1 shown in this diagram includes a structure model generation unit 11, a particle generation unit 12, a setting unit 13, an operation unit 14, and a display unit 15. Each element that the analyzer apparatus 1 includes may be a computer that includes a central processing unit and a storage unit, and the processes of each element may be executed by a program. The program is stored in the storage unit that the analyzer apparatus 1 includes, and can be recorded in a recording medium, such as a magnetic disk, an optical disk, or a semiconductor memory, and can be provided via a network.

The structure model generation unit 11 generates a structure model (a three-dimensional model) obtained by modeling an underground structure through CAD. The structure model generation unit 11 may receive a structure model generated by another device. The structure model generation unit 11 divides the structure model into a finite number of elements (mesh) used by FEM.

The particle generation unit 12 generates SPH particles by discretizing and modeling soil, and fills the peripheries of the structure model with the particles. At this time, the particle generation unit 12 sets the particle diameter of the SPH particles so as to appropriately bring the SPH particles into contact with main contact portions between the SPH particles and the structure model such that the after-mentioned processing time period of the operation unit 14 falls within a predetermined time period, and a favorable analysis result can be obtained. If the particle diameter of the SPH particles is small, an analysis result with a sufficient accuracy can be obtained but the processing time period increases. If the particle diameter of the SPH particles is large, a correct analysis result cannot be obtained. In this embodiment, the particle generation unit 12 sets the maximum diameter of the particles that does not cause indication of a time history result underestimating a pull-out resistance force that is a result of the analysis.

The setting unit 13 sets various parameters required for analysis processes. For example, the setting includes element coordinate system setting, material characteristic value setting, boundary condition setting, and external condition setting.

The operation unit 14 applies the FEM and the SPH method, and performs coupled analysis to the structure model and the SPH particles.

The display unit 15 displays an analysis result by the operation unit 14. For example, the display unit 15 displays the analysis result by a vector diagram, contours, a time history diagram, animation or the like.

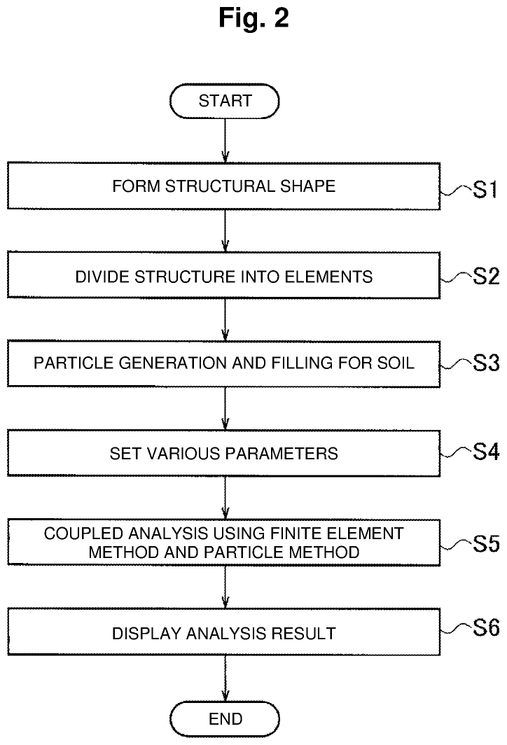

Referring to FIG. 2, the operation of the analyzer apparatus 1 of this embodiment is described.

In step S1, the structure model generation unit 11 forms a structure model of an underground structure to be analyzed.

In step S2, the structure model generation unit 11 divides the structure model into a finite number of elements.

In step S3, the particle generation unit 12 generates SPH particles by discretizing and modeling soil, and fills the peripheries of the structure model with the particles.

In step S4, the setting unit 13 sets various parameters required for analysis.

In step S5, the operation unit 14 applies the FEM and the SPH method, and performs coupled analysis for an underground structure pull-out test.

In step S6, the display unit 15 displays an analysis result.

Next, an example of numerical analysis of the pull-out test of the guyline lower anchor by the analyzer apparatus 1 in this embodiment is described.

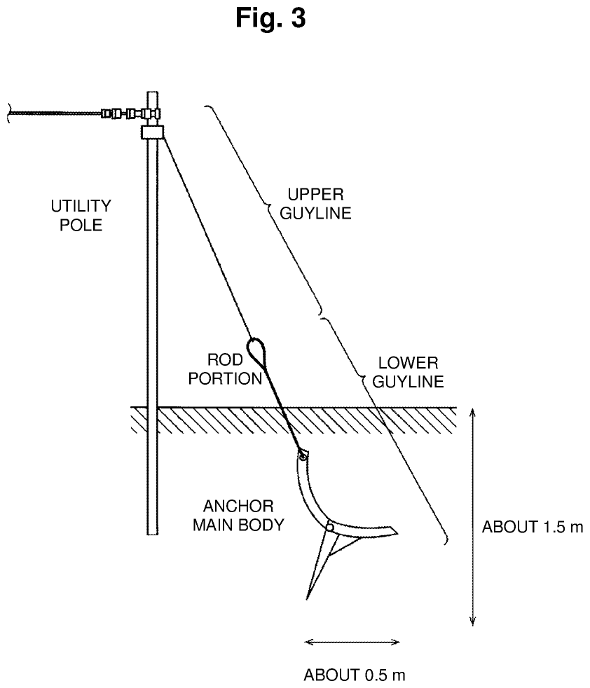

As shown in FIG. 3, to balance the force applied to the utility pole that allows the communication cable to extend, a guyline is provided for the utility pole. The guyline includes an upper guyline (steel strand wire) and a lower guyline. The lower guyline includes a rod portion (steel rod) directly connected to the upper guyline, and an anchor main body buried in the ground. The rod portion and the anchor main body are fastened with each other with a bolt inserted into a strap. A pull-out force from the rod portion is applied to the anchor main body.

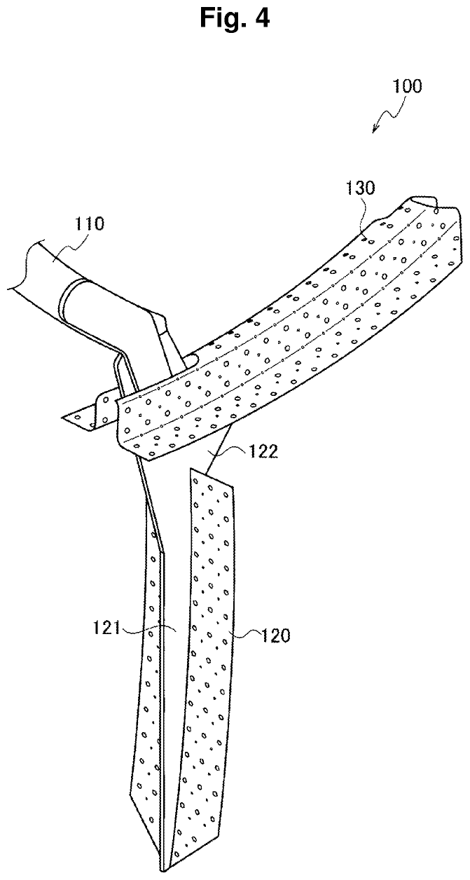

As shown in FIG. 4, the anchor main body 100 includes three portions that are a guide plate 110, a resistance plate 120, and a stabilizer plate 130. The guide plate 110 is connected to the rod portion. A steel plate called a directional plate 121 is welded to the resistance plate 120 perpendicularly to the plane direction. A triangular-shaped projection base (steel plate) called a stabilizer plate receiver 122 resides at a portion of the resistance plate 120 closer to the stabilizer plate 130.

A guyline lower anchor pull-out test with a load being applied to the loop of the rod portion is numerically analyzed using the analyzer apparatus 1, with variation in particle diameter of SPH particles.

The upper surface of the stabilizer plate 130 serves as a main contact surface with soil when the guyline lower anchor is pulled out. The upper surface of the stabilizer plate 130 is line-symmetric. Accordingly, half the stabilizer plate 130 is used as the structure model. The width of the halved stabilizer plate 130 is 50 mm.

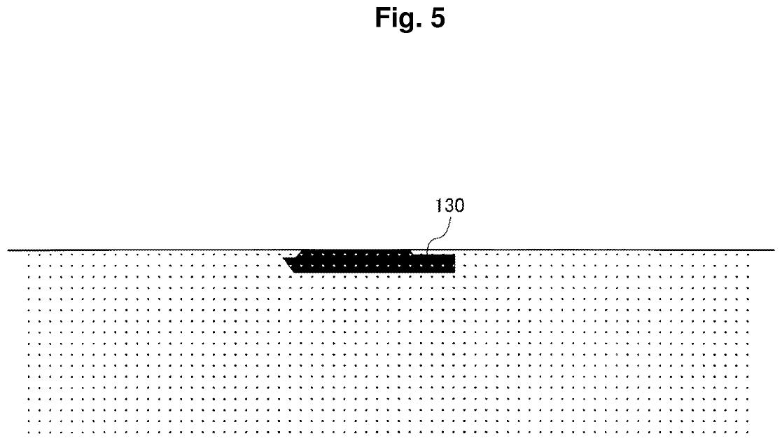

Soil assumed to be affected by the pull-out test on the halved stabilizer plate 130 is modeled. FIG. 5 shows the structure model, and the positions of the SPH particles in a case where the particle diameter is 30 mm. Provided that the particle diameter is 30 mm, two rows×16 points of SPH particles are on the structure model with a width of 50 mm, and half the soil is represented as 17 rows×67 points of SPH particles.

The interval of particles (the distance between centers of particles) is substantially identical to the particle diameter. The interval between particles varies with the particle diameter. Provided that the particle diameter is 50 mm or more, the number of SPH particles representing the soil decreases, and the number of rows of SPH particles on the structure model is one or less. Provided that the particle diameter is less than 30 mm, the number of SPH particles representing the soil increases, and the number of rows of SPH particles on the structure model is three or more.

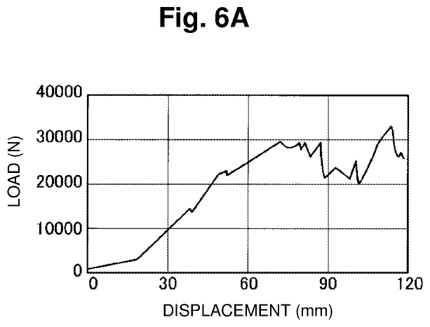

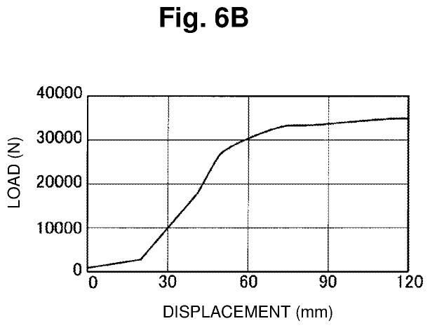

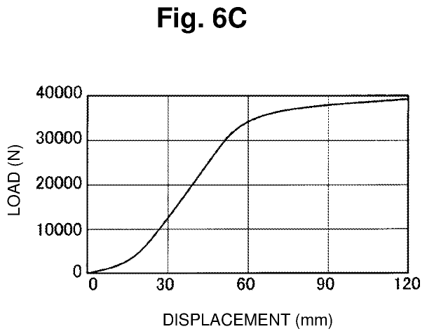

FIGS. 6A to 6C show numerical analysis results in a case where the number of rows of SPH particles on the stabilizer plate 130 is changed. The graphs of FIGS. 6A to 6C show the relationship with the displacement indicating a pull-out situation of the guyline lower anchor by a load when the load is applied to the loop of the rod portion.

The graph of FIG. 6A shows a numerical analysis result in a case where a single row of SPH particles is on the stabilizer plate 130. When the particle diameter is 50 mm or more, one row or less of SHP particles are on the surface of the structure model of the stabilizer plate 130 having a width of 50 mm. When the SPH particle diameter is wider than the width of the structure model, the structure model slips between the particles. Accordingly, the pull-out resistance force significantly decreases. When the SPH particle diameter is 50 mm, only one row or less of SPH particles are on the surface of the structure model. Accordingly, pulling out easily slides particles on the anchor surface. Consequently, a time history result underestimating the pull-out resistance force repeatedly occurs. Accordingly, correct calculation cannot be achieved. That is, as shown in FIG. 6A, the graph indicating the numerical analysis result is jagged. Note that the calculation execution time period by Intel Xeon CPU 8 cores was about 25 hours.

The graph of FIG. 6B shows a numerical analysis result in a case where two rows of SPH particles are on the stabilizer plate 130. When the particle diameter is 30 mm or more and less than 50 mm, as shown in FIG. 5, two rows of SHP particles are on the surface of the structure model of the stabilizer plate 130 having a width of 50 mm. When two rows of SPH particles are on the surface of the structure model of the stabilizer plate 130, the calculated resistance force is about a nominal ground bearing force 30 kN of the lower guyline anchor, and is relatively correct. As shown in FIG. 6B, the graph indicating the numerical analysis result is not jagged, and indicates no time history result underestimating the pull-out resistance force. Note that the calculation execution time period by Intel Xeon CPU 8 cores was about 45 hours.

The graph of FIG. 6C shows a numerical analysis result in a case where three rows of SPH particles are on the stabilizer plate 130. When the particle diameter is less than 30 mm, three or more rows of SHP particles are on the surface of the structure model of the stabilizer plate 130 having a width of 50 mm. Soil modeled with SPH particles having a smaller particle diameter has a sufficient representational power, and the pull-out resistance force can be calculated with a sufficient accuracy. However, half the soil is represented with a more number of SPH particles than that in FIG. 5. Accordingly, the amount of calculation explosively increases. With a certain capacity, a non-realistic time period is required, and a result causing a practical problem is caused. Note that the calculation execution time period by Intel Xeon CPU 8 cores was about 125 hours or more.

As described above, according to this embodiment, the structure model generation unit 11 generates the structure model where the underground structure is modeled. The particle generation unit 12 sets the maximum diameter of the SPH particles that does not cause indication of a time history result underestimating the pull-out resistance force as the analysis result, and generates SPH particles where soil as a supporter of the underground structure is modeled. The operation unit 14 applies coupled analysis to the structure model and the SPH particles respectively by the finite element method and the SPH method. According to the series of operations, this embodiment appropriately sets the diameter of SPH particles where soil is modeled, and can solve the tradeoff between the accuracy of the model and the amount of calculation, in numerical analysis that simulates the underground structure pull-out test.

### REFERENCE SINGS LIST

1 Analyzer apparatus
11 Structure model generation unit
12 Particle generation unit
13 Setting unit
14 Operation unit
15 Display unit
100 Anchor main body
110 Guide plate
120 Resistance plate
121 Directional plate
122 Stabilizer plate receiver
130 Stabilizer plate

1. An analyzer apparatus, comprising:
a structure model generation unit that generates a structure model obtained by modeling an underground structure;
a particle generation unit that generates particles obtained by modeling soil that is a supporter of the underground structure; and
an operation unit that applies coupled analysis to the structure model and the particles by a finite element method and an SPH method,
wherein the particle generation unit sets a maximum diameter of the particles that does not cause indication of a time history result underestimating a pull-out resistance force that is a result of the analysis.

2. The analyzer apparatus according to claim 1,
wherein the underground structure is a lower guyline anchor, and
the particle generation unit sets a diameter of the particles such that the particles are in double-row contact with the structure model at a main contact portion between the particles and the structure model.
